(19) United States
(12) Patent Application Publication
(10) Pub. No.: US 2007/0254154 A1
(43) Pub. Date: Nov. 1, 2007

(54) Large-Scale Synthesis of Perovskite Nanostructures

(76) Inventors: Stanislaus Wong, Stony Brook, NY (US); Yuanbing Mao, Los Angeles, CA (US)

Correspondence Address: SCULLY SCOTT MURPHY & PRESSER, PC, 400 GARDEN CITY PLAZA, SUITE 300, GARDEN CITY, NY, 11530, US

(21) Appl. No.: 11/628,564

(22) PCT Filed: Jun. 3, 2005
(86) PCT No.: PCT/US05/19668

§ 371 Date: Dec. 4, 2006

Related U.S. Application Data
(60) Provisional application No. 60/576,533, filed on Jun. 3, 2004.

(51) Int. Cl. H01L 21/20; D02G 3/00; B32B 5/16; D01F 9/12; C01G 23/00

(52) U.S. Cl. 428/402; 428/401; 423/598; 977/762; 423/447.1

(57) ABSTRACT

Nanoscale (less than 100 nm) ferroelectric materials are provided using a facile, largescale, environmentally friendly solid-state reaction. Specifically, the solid-state reaction produces perovskite nanowires, perovskite nanocubes, and/or perovskite nanoparticles which can be employed in numerous electronic applications. The solid-state reaction includes reacting a perovskite precursor, i.e., metal oxalate(s), and a metal oxide nanostructural template in the presence of an alkali salt and a surfactant.

The present invention relates to nanoscale ferroelectric materials, and more particularly to perovskite nanostructures such as nanocubes, nanoparticles, and nanowires, i.e., nanorods, as well as a method of synthesizing the same.

Nanostructures, such as nanoparticles, nanorods, nanowires, nanocubes, and nanotubes, have attracted extensive synthetic attention as a result of their size-dependent properties. See, for example, J. Hu, et al., Acc. Chem. Res., 1999, 32, 435; G. R. Patzke, et al., Angew. Chem., Int. Ed., 2002, 41, 2446; Y. Xia, et al., Adv. Mater., 2003, 15, 353; and C. N. Rao, Dalton Trans., 2003, 1. However, part of the challenge of developing practical nanoscale devices for a variety of applications is the ability to synthesize and characterize these nanostructures to rationally exploit their nanoscale optical, electronic, thermal, and mechanical properties.

Strategies for the preparation of 1-D nanowires include formation from a confined alloy droplet, as described by the vapor-liquid-solid (VLS) growth mechanism, the kinetic growth through the use of capping reagents, the generation through a chimie douce solution chemical methodology and the use of template-inspired methodologies. See, for example, Hu, et al.; G. R. Patzke, et al.; and Y. Xia, et al., ibid. as well as Y. Wu, et al., Chem. Eur. J., 2002, 8, 1260; V. F. Puntes, et al., Science, 2001, 291, 2115; J. H. Song, et al., J. Am. Chem. Soc., 2001, 123, 9714; M. Mo, et al., Adv. Mater., 2002, 14, 1658; and J. K. N. Mbindyo, et al., J. Am. Chem. Soc., 2002, 124, 4020.

Comparatively, little work has been performed on the fabrication of technologically important ternary perovskite transition metal nanostructures. See. For example, J. J. Urban, et al., Adv. Mater., 2003, 15, 2003. Perovskite structures, including BaTiO₃, SrTiO₃, BaZrO₃, SrZrO₃, and their complex, such as BaₓSrₗ₋ₓTiO₃, CaₓSrₗ₋ₓTiO₃, and BaTiₓZrₗ₋ₓO₃, are noteworthy for their advantageous dielectric, piezoelectric, electrostrictive, pyroelectric and electro-optic properties with the corresponding applications in the electronics industry for electromechanical devices, pyroelectronic detectors, imaging devices, optical memories, modulators, deflectors, transducers, actuators, capacitors, dynamic random access memory, field effect transistors, logic circuitry and high-k dielectric constant materials. Such properties and applications for perovskite oxides are described, for example, in N. A. Hill, J. Phys. Chem. B, 2000, 104, 6694, J. F. Scott, Ferroelectr. Rev., 1998, 1, 1, and A. J. Millis, Nature, 1998, 392, 147.

As reported by T. K. Song, et al., Solid State Commun., 1996, 97, 143, the perovskite oxides including, for example, but not limited to, BaTiO₃ and SrTiO₃, typically exhibit nonlinear optical coefficients and large dielectric constants. Because these effects are dependent on the metallic elemental ratios, impurities, microstructure and finite size, considerable effort has been expended in the controllable synthesis of crystalline materials and thin films of these ferroelectric oxides. See, in this regard, L. A. Willis, et al., Appl. Phys. Lett., 1992, 60, 41, J. Zhang, et al., Appl. Phys. Lett., 1994, 64, 2410, J. Zhao, et al., J. Mater. Chem., 1997, 7, 933, and X. W. Wang, et al., Mater. Sci. Eng. B, 2001, 86, 29.

One-dimensional nanotube/nanowire systems offer fundamental scientific opportunities for investigating the influence of size and dimensionality of materials with respect to their collective optical, magnetic and electrochemical properties. S. O'Brien, et al., J. Am. Chem. Soc., 2001, 123, 12085 have reported the fabrication of monodispersed nanoparticles of barium titanate with diameters ranging from 6 to 12 nm.

Additionally, BaTiO₃ and SrTiO₃ nanorods have been fabricated by solution-phase decomposition of bimetallic alkoxide precursors in the presence of coordinating ligands, yielding well-isolated nanorods with diameters ranging from 5 to 60 nm and lengths up to >10 microns. The fabrication of nanorods using the solution-phase decomposition method has been described, for example, in J. J. Urban, et al., J. Am. Chem. Soc., 2002, 124, 1186 and W. S. Yun, et al., Nano Lett., 2002, 2, 447. It is evident, from these studies, that the structures of the barium, strontium, and titanium precursors used play an important role in determining the composition, particle size and monodispersity, morphology, and properties of the final product.

In addition to fabricating nanorods, the prior art also includes various methods of fabricating nanotubes. Nanotubes differ from nanorods because nanotubes typically have a hollow cavity, whereas nanorods are completely filled nanomaterials. BaTiO₃ and PbTiO₃ nanotubes have been developed using a sol-gel template synthesis process. Such a process is described, for example, by B. A. Hernandez, et al., Chem. Mater., 2002, 14, 480, and B. A. Hernandez, et al., J. Korean Chem. Soc., 2002, 46, No. 3, 242. The prior art sol-gel template process produces hollow nanotube bundles that have an outer diameter of 200 nm and a length of about 50 μm. The nanotube bundles produced using the sol-gel template process disclosed by B. A. Hernandez, et al. are not ordered arrays, but instead are comprised of ‘spaghetti-like’ tangles that cannot be used for molecular electronic applications.

Other techniques besides the sol-gel template synthesis process disclosed in the Hernandez, et al. references have also been employed in fabricating ferroelectric nanotubes. F. D. Morrison, et al., Los Alamos National Laboratory, Preprint Archive, Condensed Matter (2003), pp. 1-19 describe the fabrication of ferroelectric nanotubes using misted chemical solution deposition (mCVD) and pore wetting.

U.S. Patent Publication 2003/0026985 A1 to Griener, et al. describes the formation of hollow fiber nanotubes having an internal diameter from 1 nm to 100 nm. The hollow nanotubes of this reference are produced by coating a degradable material with a non-degradable material and then degrading the degradable material. The prior art nanotubes disclosed in the Griener, et al. publication are biphasic and have significant amounts of amorphous impurities due to the nature in which the nanotubes are produced. By “biphasic”, it is meant that the prior art nanotubes contain two very different materials with distinctive properties having a defined interface therebetween.

In many of the prior art methods described above, organometallic precursors, which are extremely toxic, expensive, unstable, explosive and/or pyrophoric, are employed. In addition, many of the prior art methods require that a high-temperature annealing process be used. As such, the prior art methods of fabricating perovskite nanostructures include harsh reaction conditions that may have an adverse effect on the resultant nanostructure. Moreover, the prior art solution processes of fabricating perovskite nanostructures yield relatively small quantities of the desired nanostructure. Thus, the development of gram-scale and environmentally friendly synthetic methods with reproducible shape control is highly desirable if the full potential of perovskite nanostructures is to be realized.

In view of the drawbacks mentioned with the prior art methods of fabricating perovskite nanostructures, there is a continued need for providing a relatively simple and cost effective means for fabricating perovskite nanostructures in which the shape of the nanostructure can be reproducibly controlled.

The present invention relates to single crystalline perovskite nanostructures as well as a method of fabricating the same. The term “single crystalline” denotes that each of the nanostructures of the present invention has a single phase, e.g., a cubic crystalline structure, in which there are no defects or dislocations throughout the structure. The term “single phase” means there are no defects or dislocations existing in each of the nanostructures. Hence, the inventive nanostructures are comprised of single-crystalline components, i.e., perovskite; therefore no interface is present in the inventive nanostructures. The term “no interface” means that the lattice of each cube or wire is continuous and single crystalline.

More specifically, the present invention relates to single crystalline perovskite nanocubes and single crystalline perovskite nanowires that can be reproducibly fabricated using a large-scale and facile solid-state reaction. The exact type of nanostructure, i.e., nanowire, nanoparticles, or nanocube, fabricated in the present invention is dependent upon the reaction conditions employed.

The perovskite nanocubes of the present invention are characterized as having an edge length from about 1 nm to less than about 1 micron, preferably about 70 nm to about 90 nm, and even more preferably about 80 nm. The nanocubes of the present invention contain very few, if any amorphous impurities therein. Moreover, the nanocubes of the present invention are substantially free of defects or dislocations.

The perovskite nanoparticles of the present invention have a diameter of about 1 nm to less than about 1 micron, preferably about 75 nm to about 110 nm. The perovskite nanoparticles of the present invention contain very few, if any amorphous impurities therein. Moreover, the nanoparticles of the present invention are substantially free of defects or dislocations. The nanoparticles of the present invention typically have a very thin outer surface (about 1 nm or less) that contains amorphous carbon. No oxygenated groups, such as COOH or OH, which are typically present on the surface of prior art nanowires, are present on the outer surface of the inventive nanoparticles. These characteristic features of the outer surface of the inventive nanoparticles are the same for the nanocubes of the present invention.

The perovskite nanowires of the present invention are nanorods that have a diameter of about 1 nm to less than about 1 micron, preferably about 50 nm to about 80 nm and a length that is about 0.5 μm to about 50 μm, preferably about 1.5 μm or greater. The nanowires are completely filled nanomaterials, e.g., nanorods not nanotubes. The nanowires of the present invention have an aspect ratio that is on the order of about 2:1 or greater. Preferably, from about 2:1 to about 1000:1. The perovskite nanowires of the present invention contain very few, if any amorphous impurities therein. Moreover, the nanowires of the present invention are substantially free of defects or dislocations. The nanowires of the present invention typically have a very thin outer surface (about 1 nm or less) that contains amorphous carbon. No oxygenated groups, such as COOH or OH, which are typically present on the surface of prior art nanowires, are present on the outer surface of the inventive nanowires. These characteristic features of the outer surface of the inventive nanowires are the same for the nanocubes of the present invention.

Another characteristic feature of the nanocubes, nanoparticles, and nanowires of the present invention is that the inventive nanostructures are pristine materials that lack a grainy surface. The presence of a grainy surface tends to increase the surface roughness of the nanostructure. Instead, the nanostructures of the present invention have an essentially smooth surface.

In addition to the nanostructures mentioned above, the present invention also provides a method of forming such single crystalline nanostructures. The method of the present invention is a simple solid-state synthesis reaction that employs environmentally friendly reactants. Moreover, the method of the present invention can be scaled up readily to provide gram-scale synthesis of perovskite nanostructures. Specifically, the method of the present invention comprises:

admixing at least a metal oxide nanostructural template, metal oxalate precursor compounds comprising metals having positive formula charges of 1 to 3, a surfactant and a salt that is non-reactive with the metal oxide nanostructural template and the metal oxalate precursor to provide a reaction mixture;

sonicating the reaction mixture;

heating the reaction mixture to grow and synthesize perovskite nanostructures; and recovering perovskite nanocubes, nanoparticles, nanowires or a mixture thereof from said heated reaction mixture by filtration or centrifugation.

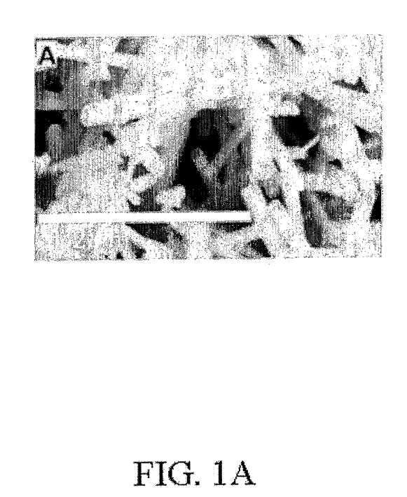

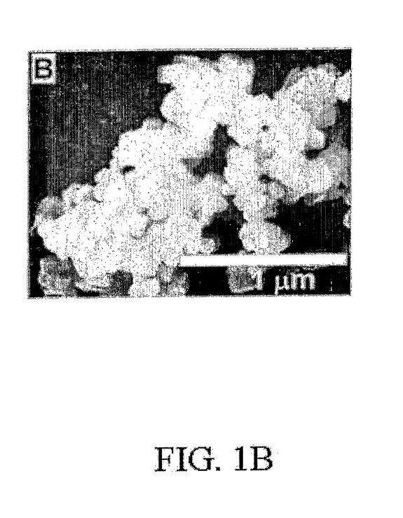

FIGS. 1A-1B are scanning electron microscopy (SEM) images of as-prepared BaTiO₃ nanowires, FIG. 1A, and SrTiO₃ nanocubes, FIG. 1B.

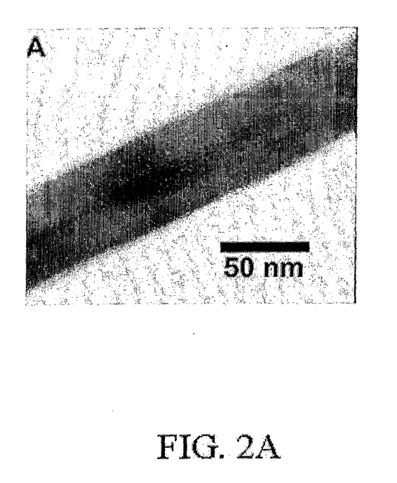

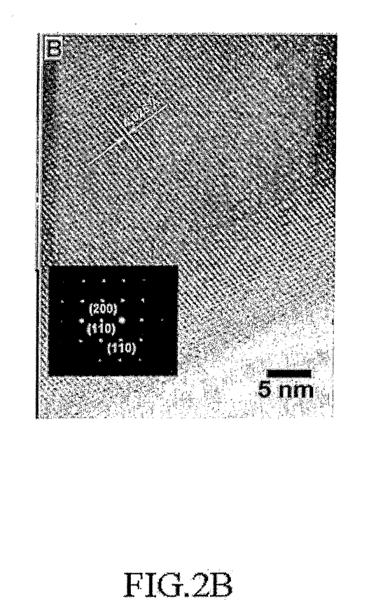

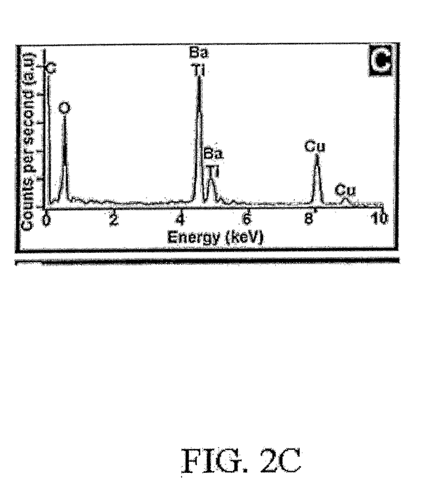

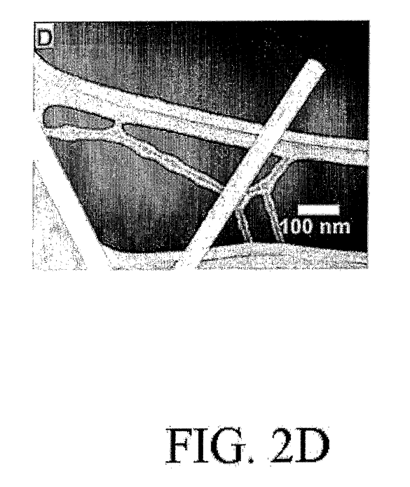

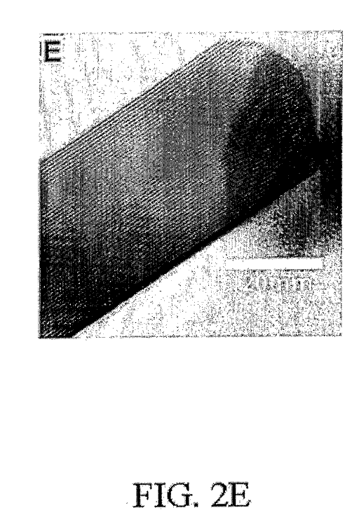

FIGS. 2A-2E are transmission electron microscope (TEM) images and energy-dispersive X-ray spectroscopy (EDS) data of the inventive BaTiO₃ nanowire, where (2A) is a typical TEM image of the inventive BaTiO₃ nanowire, (2B) is a high-resolution TEM (HRTEM) image of a portion of the nanowire of FIG. 2A (inset of 2B is a selected area electron diffraction (SAED) pattern of a BaTiO₃ nanowire), (2C) is an EDS of the BaTiO₃ nanowire, (2D) is a TEM image of the inventive BaTiO₃ nanowire, and (2E) is a HRTERM of representative tips of the inventive BaTiO₃ nanowire.

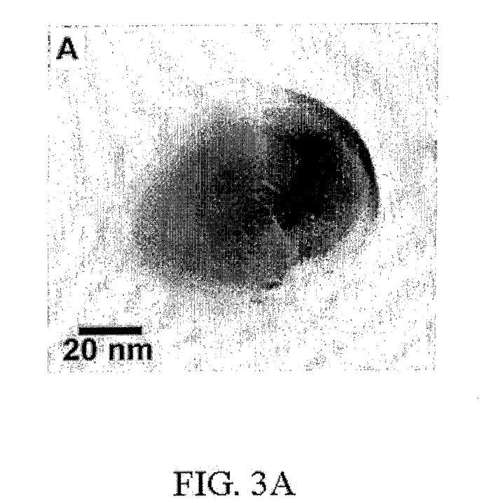

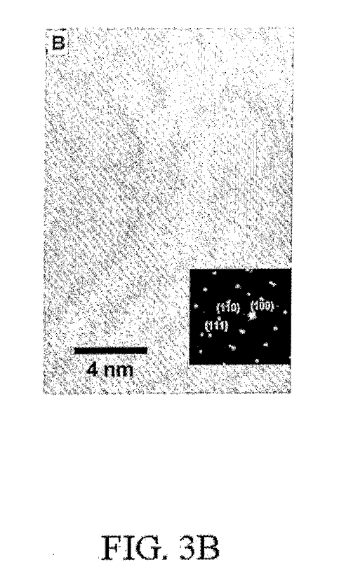

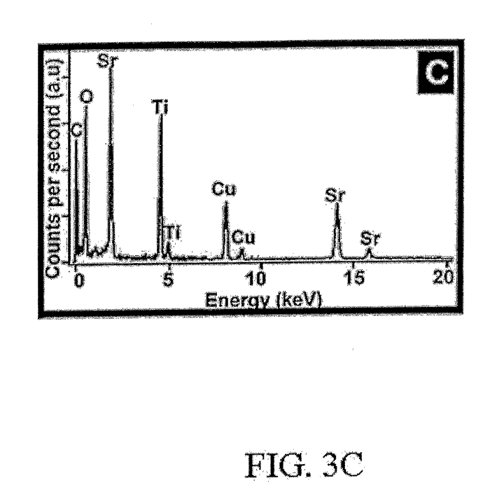

FIGS. 3A-3C are TEM images and EDS data of SrTiO₃ nanocubes prepared in accordance with the present invention, where (3A) is the TEM of an individual SrTiO₃ nanocube, (3B) is HRTEM image of FIG. 3A showing the crystal lattices corresponding to the cubic phase (inset of 3B is a corresponding SAED pattern of the as-prepared SrTiO₃ nanocubes), and (3C) is the EDS analysis of the SrTiO₃ nanocubes.

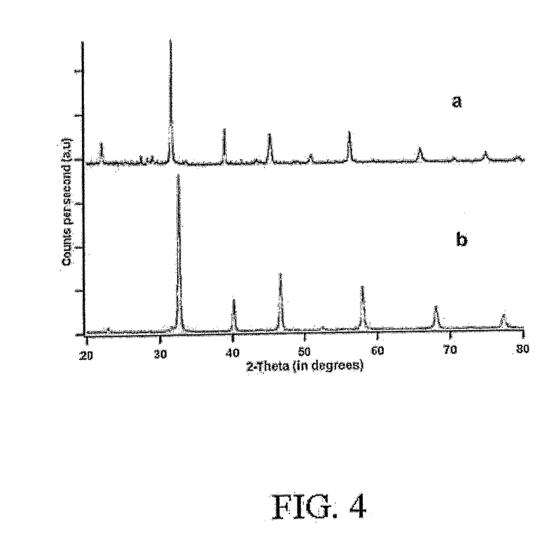

FIGS. 4A-4B are X-ray diffraction (XRD) patterns of as-prepared BaTiO₃ nanowires, FIG. 4A, and SrTiO₃ nanocubes, FIG. 4B.

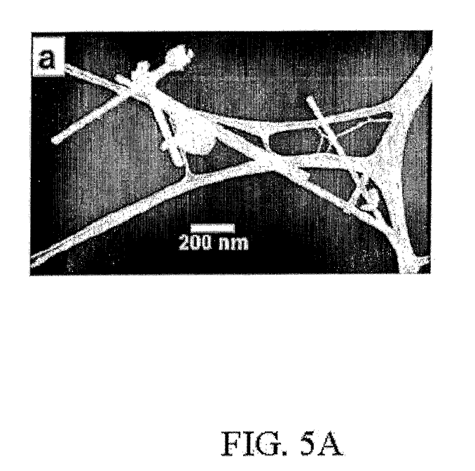

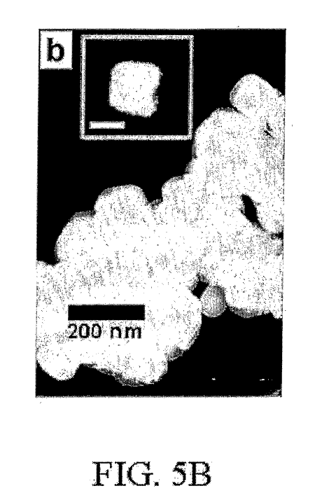

FIGS. 5A-5B are transmission electron microscopy (TEM) images of as-prepared BaTiO₃ nanowires, FIG. 5A, and SrTiO₃ nanocubes, FIG. 5B.

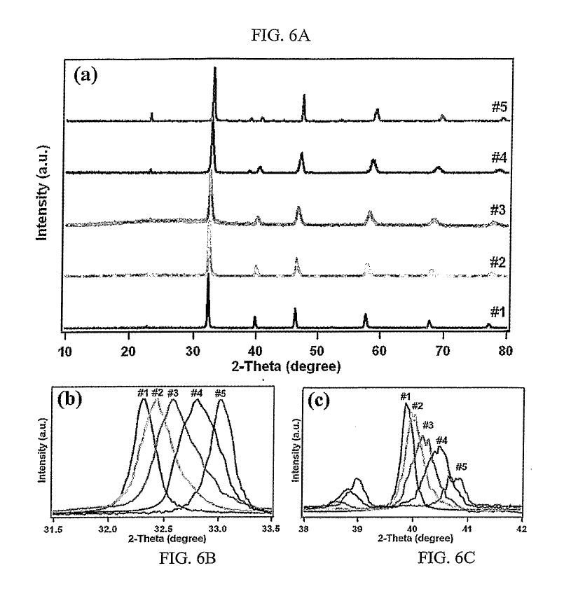

FIGS. 6A-6C are x-ray diffraction (XRD) patterns of as-prepared CaₓSrₗ₋ₓTiO₃ (0<x<1) nanoparticle samples in the 2θ range of 10 to 80°, FIG. 6A: (#1) SrTiO₃, (#2) Ca_{0.3}Sr_{0.7}TiO₃, (#3) Ca_{0.5}Sr_{0.5}TiO₃, (#4) Ca_{0.7}Sr_{0.3}TiO₃, and (#5) CaTiO₃. Labels are identical for FIG. 6B and FIG. 6C. FIG. 6B shows the 2θ diffraction peak around 32.5° for the samples of all five compositions. These illustrate the gradual increase in lattice parameter observed as a function of increasing calcium concentration in CaₓSrₗ₋ₓTiO₃ (0<x<1) nanoparticles. FIG. 6C demonstrates the 2θ diffraction peaks centered at 40° for the samples of all five compositions, showing the phases of as-prepared CaₓSrₗ₋ₓTiO₃ (0<x<1) nanoparticles varying from cubic to tetragonal to orthorhombic with decreasing ‘x’ content.

FIGS. 7A-7E are SEM images of as-prepared samples of SrTiO₃, FIG. 7A, Ca_{0.3}Sr_{0.7}TiO₃, FIG. 7B, Ca_{0.5}Sr_{0.5}TiO₃, FIG. 7C, Ca_{0.7}Sr_{0.3}TiO₃, FIG. 7D, and CaTiO₃, FIG. 7E, while FIG. 7F is the EDS data of the as-synthesized CST nanoparticles, where (#1) SrTiO₃, (#2) Ca_{0.3}Sr_{0.7}TiO₃, (#3) Ca_{0.5}Sr_{0.5}TiO₃, (#4) Ca_{0.7}Sr_{0.3}TiO₃, and (#5) CaTiO₃. The intensity of the peaks for each sample has been normalized based on the intensity of the Ti peak.

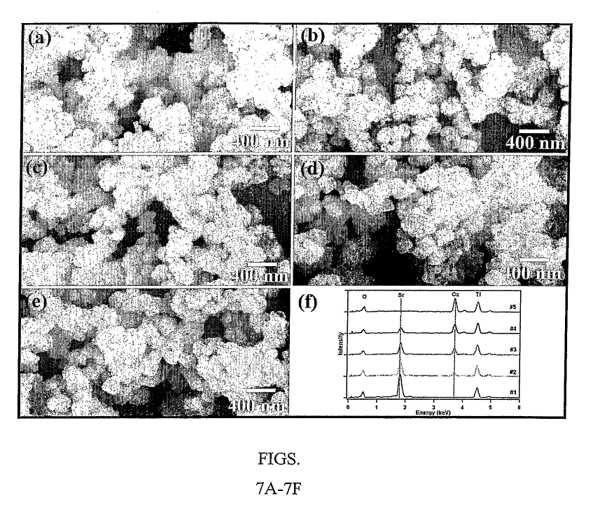

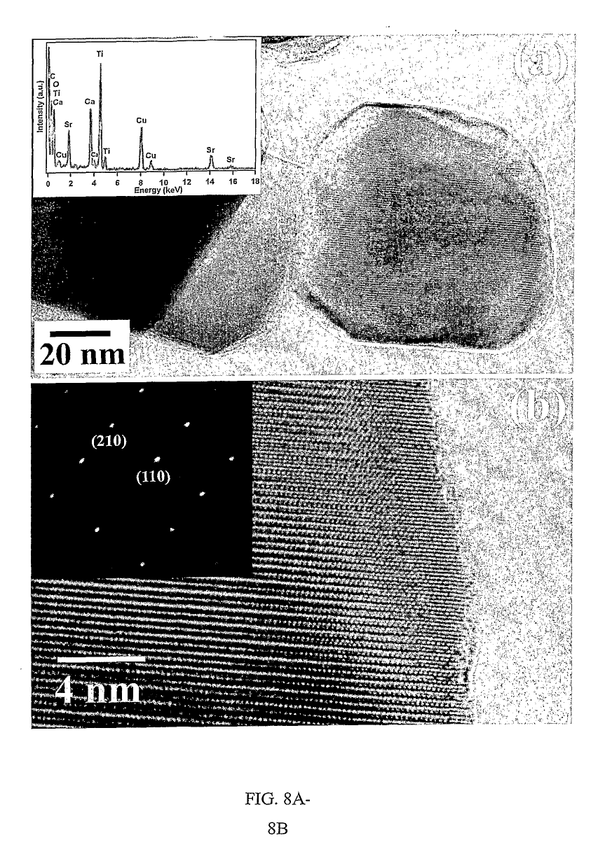

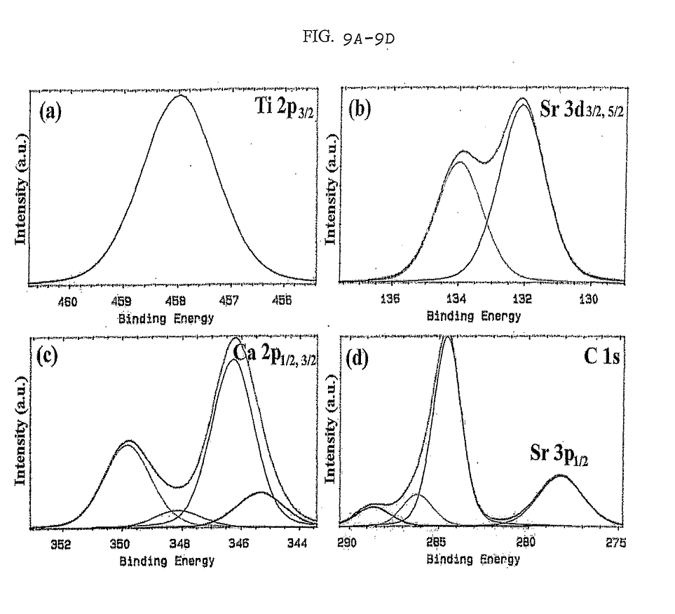

FIG. 8A-8B are TEM and HTREM images of Ca_{0.7}Sr_{0.3}TiO₃ nanoparticles prepared in accordance with the present invention, where FIG. 8A is the typical TEM of an as-prepared Ca_{0.7}Sr_{0.3}TiO₃ nanoparticle sample (inset of 10A is the EDS data of an as-synthesized Ca_{0.7}Sr_{0.3}TiO₃ nanoparticle), (10B) is HRTEM image of a region within FIG. 10A showing the crystal lattices corresponding to orthorhombic crystalline Ca_{0.7}Sr_{0.3}TiO₃ (inset of 10B is a corresponding SAED pattern of the as-prepared Ca_{0.7}Sr_{0.3}TiO₃ nanoparticle).

FIGS. 9A-9D is the XPS data of an as-prepared Ca_{0.3}Sr_{0.7}TiO₃ nanoparticle sample (Binding energy in eV): Ti 2p_{3/2} spectra, FIG. 9A, Sr 3d spectra, FIG. 9B, Ca 2p spectra, FIG. 9C, and C 1s spectra, FIG. 9D.

As stated above, the present invention provides perovskite nanocubes, nanoparticles, and/or nanowires that are single crystalline compositions of matter. The perovskite nanostructures of the present invention have a structural formula ABO₃ wherein B is at least one metal selected from Group IIIA, IVA, IVB, VB, VIB, VIIB, or VIIIB of the Periodic Table of Elements (CAS version), and A is at least one additional cation having a positive formula charge of from about 1 to about 3.

In the above formula, component A of the perovskite nanostructure comprises a cation selected from the group consisting of K, Na, Rb, Cs, Li, Ba, Sr, Zr, Ta, La, Pb, Zn, Ca, Sc, Y, Bi, an element from the Lanthanide-series, an element from the Actinide-series, and mixtures thereof. In the present invention, it is highly preferred that component A of the perovskite nanostructure is a cation of Ba, Sr and/or Ca.

Insofar as component B of the perovskite nanostructure is concerned, component B may include any metal within the group of metals listed above. Thus, for example, the B component of the perovskite nanostructure may include a metal such as, for example, Ti, Zr, Hf, V, Nb, Ni, Fe, Co, Ta, Cr, Mo, W, Mn, Tc, Re, Ge, Sn, Ru, Os, Cd, Hg, Rh, Ir, Pd, Pt, Cu, Bi, I, Al, Ce, Th, and/or In, and mixtures thereof. Of these metals, it is highly preferred that Ti be used as the B component of the perovskite nanostructure of the present invention.

When Ti is employed as the B component in the above formula, titanate-based perovskites having the formula ATiO₃ are synthesized. Examples of such types of titanate-based nanostructures that may be formed in the present invention include, but are not limited to: barium strontium titanate (BaₓSrₗ₋ₓ)TiO₃; BSTO), barium titanate (BaTiO₃; BTO), strontium titanate (SrTiO₃; STO), strontium calcium titanate (CaₓSrₗ₋ₓTiO₃; CSTO), lead zirconium titanate (Pb(Zr_{y}Ti_{l-y})O₃; PZTO), barium zirconium titanate (Ba(Zr_{y}T_{l-y})O₃; BZTO), and lead lanthanum titanate ((Pbₗ₋ₓLaₓ)TiO₃; PLTO). Of the foregoing mentioned titanate-based nanomaterials, it is highly preferred in the present invention that the perovskite nanostructures formed comprise barium titanate, BaTiO₃, strontium titanate, SrTiO₃, or a series of strontium calcium titanate, CaₓSrₗ₋ₓTiO₃ (0<x<1). In one embodiment of the present invention, it is preferred that the nanowires are comprised of BaTiO₃. In another embodiment of the present invention, it is preferred that the nanocubes are comprised of SrTiO₃. In yet another embodiment of the present invention, it is preferred that the nanoparticles are comprised of CaₓSrₗ₋ₓTiO₃ (0<x<1).

The perovskite nanowires of the present invention are one-dimensional structures that are completely filled nanomaterials. The perovskite is present entirely throughout the nanowire; therefore no interfaces exist in the inventive nanowires. The perovskite nanowires of the present invention are characterized as having a diameter from about 1 nm to less than about 1 micron, preferably from about 50 nm to about 80 nm and a length, 1, from about 0.5 μm to about 50 μm, preferably from about 1.5 μm or greater. More preferably, the perovskite nanowires of the present invention have a diameter from about 40 mn to about 120 nm and a length, 1, from about 1 μm to about 50 μm.

The perovskite nanowires of the present invention are further characterized as having an aspect ratio on the order of about 2:1 or greater, with an aspect ratio of about 2:1 to about 1000:1 being more highly preferred. The aspect ratio is based on the diameter dimension divided by the length. The inventive perovskite nanowires also are characterized as having a cubic crystalline structure that has substantially no amorphous impurities therein. The nanowires however contain a very thin (on the order of about 1 nm or less) amorphous carbon surface layer. In accordance with the present invention, the nanowires synthesized by the present invention having an amorphous impurity content of less than 1%. The nanowires of the present invention are further characterized as having no defects or dislocations and having an extremely smooth outer surface. By “extremely smooth”, it is meant a surface that has a mean square roughness value of less than about 0.5 nm RMS (root mean square) or less. Another characteristic feature of the inventive nanowires is that the outer surface thereof contains amorphous carbon, with essentially little or no groups that are oxygenated, e.g., COOH and OH. The presence of carbon as well as the absence of the surface oxygenated groups can be verified by IR spectroscopy, X-ray photoelectron spectroscopy or by using any other surface elemental analysis technique.

The nanocubes of the present invention have an edge length from about 1 nm to less than about 1 micron, preferably from about 70 nm to about 90 nm, with an edge length of about 80 nm being more typical. The nanocubes of the present invention have all the basic characteristics of the inventive nanowires, expect for the dimensions mentioned above.

The nanoparticles of the present invention have an edge length from about 1 mn to less than about 1 micron, preferably from about 75 nm to about 110 nm. The nanoparticles of the present invention have all the basic characteristics of the inventive nanowires and nanocubes, expect for the dimensions mentioned above.

The nanostructures of the present invention are prepared using a facile solid-state reaction which begins by first providing a reaction mixture that includes at least a metal oxide nanostructural template, metal oxalate precursor compounds comprising metals having positive formula charges of 1 to 3, a surfactant and a salt that is non-reactive with the metal oxide nanostructural template and the metal oxalate precursor(s). The reaction mixture is prepared by adding the aforementioned components together in a reaction vessel or flask, and then mixing the added material together. The addition of the various components can be in any order and the mixing step can be performed utilizing techniques that are well known to those skilled in the art. For example, the mixing step can be performed utilizing a conventional blender or other like mixing apparatus. During the mixing process, a homogeneous solid-state reaction mixture is provided and, in some instances, the components of the reaction mixture are typically grinded into smaller particles than that of the particle size of the initially added components.

The metal oxide nanostructural template employed in the present invention comprises a metal selected from Group IIIA, IVA, IVB, VB, VIB, VIIB, or VIIIB of the Periodic Table of Elements. Of the various metals that may be employed in the present invention, it is highly preferred that the metal oxide nanostructural template be TiO₂. Because the metal oxide nanostructural template provides the B component of the inventive perovskite nanocubes and nanowires, the inventive perovskite nanostructures can have many of the physical properties of the metal oxide nanostructural template. Hence, the length and diameter of the inventive perovskite nanowires can be derived from the length and diameter of the nanostructural template. As such, the nanostructural template is employed as a precursor material itself in order to generate the corresponding perovskite nanostructures in a controlled and rational manner.

Thus, there is at least one precursor compound employed in the present invention comprising a cation having a positive formula charge of 1 to 3 and an oxalate anion. Preferred examples of such precursor compounds include barium oxalate, strontium oxalate, and/or calcium oxalate.

The salt employed in forming the reaction includes any salt that does not react with the nanostructural template or the oxalate-containing precursor compound. Examples of such salts include alkali halides, alkali hydroxide, alkali nitrates, alkali phosphates and mixtures thereof. The term “alkali” denotes an alkali metal from Group IA of the Periodic Table of Elements, including, for example, Li, Na, K, Rb, and the like. Preferably, the alkali comprises Na or K. The term “halide” denotes F, Cl, Br and I. In one preferred embodiment, the alkali halide is NaCl.

The surfactant employed in the present invention comprises any surfactant that can serve as an emulsifying agent for the nanostructural template and the precursor. Illustratively, the surfactant can be a cationic surfactant, an anionic surfactant, an amphoteric, i.e., zwitterionic, surfactant, a nonionic surfactant or any combination thereof.

Examples of the cationic surfactants that can be used in the present invention, include, but are not limited to: cetyltrimethylanmmonium bromide and the like. Examples of anionic surfactants that can be employed in the present invention include, but are not limited to: sodium dioctyl sulfosuccinate and the like. Examples of the amphoteric surfactants that can be used in the present invention, include, but are not limited to: allyl ampho(di)acetates and the like. Examples of nonionic surfactants that can be used in the present invention, include, but are not limited to: alkyl aryl ether and the like. Of the various type of surfactants mentioned above, it is preferred that nonionic surfactants such as an alkyl aryl ether be employed. In one embodiment, the alkyl aryl ether is nonylphenyl ether. The foregoing surfactants are provided for illustrative purposes and the present invention is not limited to the surfactants listed above. An exhaustive list of various surfactants that can be used in the present invention can be found in McCutcheon's Emulsifiers & Detergents, Vol. 1, North American Edition. It is noted that the above list provides examples of some types of surfactants that can be employed in the present invention. Other surfactants that are well known to those skilled in the art can also be used.

The admixing of the various components is performed at nominal room temperature (on the order of about 15°-40° C.). The molar ratio of metal oxide to the metal oxalate precursor compound used in forming the perovskite nanostructures is from about 0.9:1 to about 1:0.9, with a molar ratio of about 1:1, based on the metal oxide nanostructural template to the metal oxalate precursor compound, being more highly preferred.

The molar ratio of salt to precursor compound is from about 5:1 to about 50:1, with a molar ratio of salt to precursor of about 20:1 being more highly preferred. The molar ratio of the surfactant used in preparing the nanostructures of the present invention to precursor is from about 1:1 to about 8:1, with a molar ratio of surfactant to precursor of about 3:1 being more highly preferred.

After the admixing step, the reaction mixture is subjected to sonication. Any conventional sonication apparatus, such as, for example, a Branson 1210 model, can be used to sonicate the admixture. The sonication typically occurs at nominal room temperature in air. The sonication step is typically performed for a time period from about 1 to about 20 minutes, with a time period from about 4 to about 8 minutes being more typical.

The reaction mixture is then heated, i.e., annealed, in air at a temperature from about 810° C. to about 910° C. to facilitate the growth and formation of the perovskite nanowires, nanoparticles, and/or nanocubes. More specifically, the temperature of this heating step is from about 815° C. to about 825° C. The heating step occurs in a ceramic crucible, such as zirconium silicate boats or platinum crucibles or quartz boats, which are inserted in a reactor tube, such as a quartz tube.

The heating step is performed for a time period that is sufficient to continue the formation of perovskite nanostructures in the reaction vessel. Typically, the heating step is performed for a time period from about 0.5 hour to about 10 hours, with a time period from about 2 hours to about 4 hours being more highly preferred.

After the heating step, the sample is cooled to nominal room temperature and the inventive nanostructures are recovered using techniques well known to those skilled in the art including, for example, collection of nanostructures via centrifugation, washing the collected nanostructures with distilled water and drying. The yield of perovskite nanostructures recovered from the inventive process is typically on the order of about 80% or greater, with a yield of from about 90% to about 95% being more typical. Possible side products from the barium titanate nanowire synthesis include barium titanate nanocubes.

Small traces of amorphous carbon, less than 1%, as well as unreacted starting materials, less than 2%, may be present in the final nanostructure product.

The nanostructures of the present invention can be used in numerous molecular electronic applications such as, for example random access memory, logic circuitry, pyroelectronic detectors, imaging detectors, optical memories, modulators, deflectors, transducers, actuators, and high dielectric constant dielectrics. Additionally, the inventive nanostructures can be used for ferroelectric random access memory (FRAM) with a 1-Gbit density or higher and logic circuitry—the next generation of components for molecular electronics and molecular computers. In their stable polarization states, the inventive nanostructures can be used to encode the 1 and 0 of Boolean algebra, which forms the basis of memory and circuitry.

Illustrative examples of structures in which an assembly of the inventive nanostructures can be employed, include, for example, nanotransducers, nanoactuators, positive temperature coefficient resistors, multilayer capacitors, electo-optical device, ferroelectrics, relaxors, and thermistors. Additionally, the nanostructures of the present invention can be employed in nonvolatile memory cells and electrochemical devices.

The following example is provided to illustrate that the method of the present invention can be used for fabricating perovskite nanocubes, perovskite nanoparticles, or perovskite nanowires. The synthesis is provided as well as the TEM, SEM and X-ray diffraction data for BrTiO₃ nanowires, SrTiO₃ nanocubes, and a series of CaₓSrₗ₋ₓ)TiO₃ (0<x<1) nanoparticles.

### EXAMPLE

In a typical synthesis, barium or strontium oxalate or the mixture of calcium oxalate and strontium oxalate (depending on the desired nanostructure), TiO₂ (anatase), NaCl and NP-9 (nonylphenyl ether) were mixed (molar ratio 1:1:20:3), grounded for 25 min, and finally sonicated for 5 min. The mixture was then placed in a quartz crucible, inserted into a quartz tube, annealed at 820° C. for 3.5 h, and subsequently cooled to room temperature. Samples were collected, washed several times with distilled water, and dried at 120° C. overnight in a drying oven. This process can easily and routinely by scaling up to produce grams of single-crystalline BaTiO₃, SrTiO₃, and CaₓSrₗ₋ₓ)TiO₃ (0<x<1) nanostructures.

The purity and crystallinity of the as-prepared samples were examined using powder XRD. Very few, if any, impurity peaks were present. The peaks in FIG. 4A were indexed to the cubic lattice [space group: Pm3m] of BaTiO₃, and the calculated lattice constant was a=4.003 Å, a value in good agreement with literature results (a=4.031 Å, JCPDS no. 31-0174). Similarly, the peaks in FIG. 4B were indexed to a pure cubic phase of SrTiO₃ with a lattice constant a=3.884 Å, compatible with the literature value of a=3.905 Å (JCPDS no. 73-0661).

FIGS. 1A-1B show SEM images of the as-prepared BaTiO₃ and SrTiO₃ products, respectively. From FIG. 1A, it was evident that the BaTiO₃ product consists of straight, smooth, and crystalline wire-like structures. From the TEM results (FIG. 5A), the nanowires were ˜50-80 nm in diameter, and their lengths ranged from 1.5 μm to even longer than 10 μm. SrTiO₃ nanostructures, analogously prepared, were revealed by SEM (FIG. 1B) and TEM (FIG. 5B) to consist exclusively of nanocubes with an edge length of 80±10 nm. It was evident that there was some degree of aggregation and clumping in these wires/cubes.

Images in A and B of FIG. 2 represent the HRTEM images of the center region of one of the BaTiO₃ nanowires. While a thin amorphous layer was found on the nanowire surface, the images clearly show that BaTiO₃ nanowires were uniform and homogeneous and that the 2-D lattice fringes illustrate that the nanowire was single crystalline with no defects or dislocations. EDS analysis (FIG. 2C) from different positions along the nanowires shows that the chemical signatures of the nanowires were identical within experimental accuracy and that the nanowires were essentially composed of the elements Ba, Ti, and O. Moreover, the SAED patterns taken from different positions along the same nanowires were also identical within experimental accuracy, and the particular SAED pattern, shown here as an inset to FIG. 2B, were indexed to the reflection of a cubic BaTiO₃ structure with a lattice parameter, a=4.024 Å, which was also consistent with the XRD data. The SAED pattern further validated that the observed BaTiO₃ nanowires were single crystalline. Furthermore, the tips of as-prepared BaTiO₃ nanowires (FIG. 2, D and E) were smooth and hemispherical.

FIG. 3A shows that the SrTiO₃ nanocube was effectively square in shape. Moreover, the 2-D lattice fringes (FIG. 3B) illustrate that the nanocubes were single crystalline with no defects or dislocations. Interplanar spacings were ˜2.250 Å. EDS data indicate that these cubes were composed of Sr, Ti, and O (FIG. 3C). The SAED pattern (inset to FIG. 3B) were indexed to the reflection of a cubic SrTiO₃ structure with a=3.885 Å.

FIG. 6A shows the diffraction patterns collected on the five CaₓSrₗ₋ₓTiO₃ (0<x<1) samples in the 2θ range of 10 to 80°. Very little if any impurity peaks were present. In fact, all peaks for sample #1 in FIG. 6A can be indexed to the cubic lattice [space group: Pm3m] of SrTiO₃. The lattice constant calculated from this pattern was a=3.894 Å, a value in good agreement with literature results (a=3.905 Å, JCPDS file No. 73-0661). Similarly, the peaks for samples #5 in FIG. 6A were consistent with a pure orthorhombic phase [space group: Pbnm] of CaTiO₃ with lattice constants of a=5.379 Å, b=5.440 Å, and c=7.638 Å, which were compatible with literature values of a=5.380 Å, b=5.442 Å, and c=7.640.Å (JCPDS 22-0153). The observed reduction in symmetry from cubic to orthorhombic results from the lattice substitution of the smaller Ca⁺² ions (radius of 1.34 Å) as compared with the larger Sr⁺² ions (1.44 Å). The fact that a range of CaₓSrₗ₋ₓTiO₃ (0<x<1) solid solutions can be stably formed with increasing Ca content was due to the Sr—O bond length reduction being offset to a large degree by Ti—O bond shortening upon Ca²⁺ substitution. When all five XRD patterns were considered simultaneously, phase transition aspects in the CaₓSrₗ₋ₓTiO₃ (0<x<1) system was observed, in agreement with the results of bulk materials with identical composition levels. FIG. 6B illustrates XRD peak behavior 2θ value between 31.5° and 33.5° for all five samples. It can be clearly seen that the (110) peak corresponding to the cubic phase of SrTiO₃ shifted to higher 2θ as a function of composition, eventually transforming into the (112) peak of the orthorhombic phase of CaTiO₃. Moreover, FIG. 6C shows the XRD peak behavior of 2θ values between 38° and 42° for all five samples of CaₓSrₗ₋ₓTiO₃ (0<x<1) nanoparticles. As a function of composition, the sharp (111) peak corresponding to the cubic phase of SrTiO₃ splits into (211), (022) and (202) reflection signals due to the orthorhombic Pbnm phase of CaTiO₃. These results were consistent with the sequence of phase transitions with increasing Sr content in the CaₓSrₗ₋ₓTiO₃ (0<x<1) system as progressing from orthorhombic (Pbnm), initially when ‘x’=0, to orthorhombic (Bmmb) followed by tetragonal (I4/mcm) and ultimately to cubic (Pm3m) when ‘x’=1, as previously observed for bulk.

FIG. 7A-7E show SEM images and the EDS data of all five as-prepared CaₓSrₗ₋ₓTiO₃ (0<x<1) nanoparticle products. It was evident that the products mainly consisted of solid, crystalline nanoparticles with mean sizes below 100 mn, although the particle morphology was dependent on the crystal structure of the material. In particular, the SrTiO₃ nanoparticle sample was composed of nanosized cubes, which have distinct edges, as had been reported previously. With increasing calcium content, the sharp, distinct edges of the initial cube smoothen; most of the CaTiO₃ nanoparticles were quasi-nanospheres. As-described trends in observed shapes were reproducible but small, randomized deviations from the homogeneous shapes expected were noted in different samples. As-prepared CaₓSrₗ₋ₓTiO₃ (0<x<1) nanoparticle samples were free of hard agglomeration, although it is apparent that there is some degree of loose aggregation in these nanoparticles, accounting for the clumping observed in the SEM. Isolated nanoparticles should be readily obtainable by standard dispersion techniques, such as sonication, subject to the limitations imposed by (a) the existence of strong, attractive van der Waals forces between these particles as well as to (b) evaporation-induced aggregation resulting from SEM and TEM sample preparation. SEM images have been taken from randomly selected areas of the substrate, and as such, these are representative of the overall sizes and shapes of CaₓSrₗ₋ₓTiO₃ (0<x<1) nanoparticles in the samples. Moreover, in every CaₓSrₗ₋ₓTiO₃ (0<x<1) nanoparticle sample analyzed by EDS, elemental signals due to Sr and/or Ca, Ti, and O were reproducibly detected (FIG. 7F), as expected. In the normalized data, as the intensity of the Sr signal decreased, that of the Ca peak increased with decreasing values of ‘x’ or Sr content in the CaₓSrₗ₋ₓTiO₃ (0<x<1) system.

Additional structural and chemical analyses of the as-prepared CaₓSrₗ₋ₓTiO₃ (0<x<1) nanoparticles have been carried out with TEM, HRTEM, SAED, and EDS. Specifically, FIGS. 8A-8B provide TEM and HTREM images of Ca_{0.7}Sr_{0.3}TiO₃ nanoparticles prepared in accordance with the present invention. In addition, a low magnification TEM image of as-prepared Ca_{0.7}Sr_{0.3}TiO₃ nanoparticles was performed. From that TEM it was determined that the particles had an average diameter of 85±15 nm. The contrast difference among the various nanoparticles of the TEM image arised from the slight tilt of the particles with respect to the electron beam as well as intrinsic differences in the thicknesses of the particles themselves. Localized chemical composition analysis by EDS from various parts of individual Ca_{0.7}Sr_{0.3}TiO₃ nanoparticles indicates that these nanostructures are composed of Ca, Sr, Ti, and O. An HRTEM image was taken from a section of an as-prepared, individual Ca_{0.7}Sr_{0.3}TiO₃ nanoparticle. The 2-D lattice fringes clearly illustrate that the nanoparticle was crystalline with no defects or dislocations. Interplanar spacings are ˜1.940 Å and 1.790 ÅÅ, which correspond to the (200) and (210) planes, respectively, of orthorhombic crystalline Ca_{0.7}Sr_{0.3}TiO₃. The SAED pattern taken from the same nanoparticle is shown as an inset to FIG. 3B. It can be indexed to the reflection of an orthorhombic Ca_{0.7}Sr_{0.3}TiO₃ structure, and confirms that these nanoparticles are crystalline.

The survey XPS spectra collected on successive CaₓSrₗ₋ₓTiO₃ (0<x<1) (where ‘x’=1, 0.7, 0.5, 0.3, and 0, respectively) samples (See, FIGS. 9A-9D in which the survey XPA spectra for x=0.7 is shown) show that the amount of strontium expectedly increased while the calcium content decreased with rising ‘x’ values; the amount of detectable titanium does not alter at all. Specifically, high-resolution XPS spectra of an as-prepared sample of Ca_{0.7}Sr_{0.3}TiO₃ nanoparticles yielded information on the intrinsic nature of their chemical bonding. The Ti 2p_{3/2} spectrum was consistent with an oxidation state of Ti⁴⁺. The binding energy for this peak at 457.96 eV represented a ˜1 eV decrease, as compared with the value of 459.0 eV for bulk TiO₂. It has been suggested that the presence of Sr and Ca influences the ionic character of the Ti—O bond, resulting in an increased bond length and hence a decrease in the binding energy, as compared with TiO₂. The Ti 2p_{3/2} peak can be simulated by a single Gaussian clearly showing that no other oxidation states, which would have resulted in additional side bands, are detectable for Ti in this compound. The Sr 3d_{5/2} and 3d_{3/2} peaks were located at 132.10 eV and 133.99 eV, respectively. Similar spectra have been obtained for all five samples except for CaTiO₃. The binding energies of the Sr 3d peaks were consistent with those reported for strontium in the Sr₂₊ state, as well as for bulk SrO. The Ca 2p spectra of Ca_{0.3}Sr_{0.7}TiO₃, and Ca_{0.5}Sr_{0.5}TiO₃ can each be fitted with single doublets with a splitting of about 3.5 eV and peak widths of about 1.8 eV. For the Ca 2p spectra of Ca_{0.7}Sr_{0.3}TiO₃ and CaTiO₃, an extra secondary component was required. The resultant shift in binding energy in these systems was presumably due to the partial reduction of calcium and the fact that a non-cubic lattice was more likely to accept a variety of bonding configurations. The C 1s spectra served roles of internal energy calibration, as well as of carbonate detection and surface contamination. It was observed that the C 1s spectrum, centered at ˜285 eV, for the as-prepared sample of Ca_{0.7}Sr_{0.3}TiO₃ nanoparticles. This carbon signal was much more intense than the Sr 3p_{1/2} peak. In addition, two additional carbon peaks can be observed on the higher binding energy side, which may be due to the presence of surface carbonate species. This was not surprising considering that surface SrO or CaO shows a strong tendency to chemisorb carbon dioxide and water vapor from the air, which is consistent with the HRTEM observation of a very thin layer of amorphous carbon on the edge of CaₓSrₗ₋ₓTiO₃ (0<x<1) nanoparticles.

It is noteworthy that the use of different precursors, such as oxides and chlorides, as opposed to oxalates, produces neither phase-pure titanates nor even nanostructures. Moreover, even a slight change of reaction conditions, such as at a slightly lower temperature, i.e., 805° C., results in a lack of phase-pure titanates.

The experimental results demonstrate that maintaining identical experimental conditions, with the exception of the metal precursor (i.e. either Ba-, Sr-, or Ca-based) used, results in the production of different shapes of perovskite nanostructures. Although the fundamental basis of shape selectivity for this system is not as yet known, it is likely that wires and cubes are simply kinetically dissimilar, morphological manifestations of the same underlying growth mechanism, involving the formation of initial nuclei of the cubic form. The shape of nanocrystal can be determined by the relative specific surface energies associated with the facets of the crystal. In addition, the preferential adsorption of molecules and ions, such as chloride, to different crystal faces likely directs the growth of nanoparticles to their ultimate product morphology by controlling the growth rates along the different crystal faces. In fact, if NaCl is removed from the synthesis of BaTiO₃ nanowires, the product is randomly particulate in shape distribution. It makes little difference in the SrTiO₃ synthesis whether NaCl or surfactant is present in the reaction mixture. Moreover, if the initial barium or strontium precursor is omitted altogether, identical experimental protocols all yield cubes, consisting of a mixture of anatase and rutile.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A composition of matter comprising single crystalline perovskite nanocubes.

2. The composition of matter of claim 1 wherein said single crystalline perovskite nanocubes have an edge length from about 1 nm to less than about 1 micron.

3. The composition of matter of claim 1 wherein said single crystalline perovskite nanocubes have an edge length from about 70 mn to about 90 nm.

4. The composition of matter of claim 1 wherein said perovskite nanocube comprises a compound having the formula ABO₃ wherein B is at least one metal selected from Group IIIA, IVA, IVB, VB, VIB, VIIB, or VIIIB of the Periodic Table of Elements, and A is at least one additional cation having a positive formula charge of from about 1 to about 3.

5. The composition of matter of claim 4 wherein A is selected from the group consisting of K, Na, Rb, Cs, Li, Ba, Sr, Zr, Ta, La, Pb, Zn, Ca, Sc, Y, Bi, an element from the Lanthanide-series, an element from the Actinide-series, and mixtures thereof.

6. The composition of matter of claim 4 wherein A comprises Ba, Sr or a mixture thereof.

7. The composition of matter of claim 4 wherein A is Sr and B is Ti.

8. The composition of matter of claim 4 wherein A is Ba and B is Ti.

9. The composition of matter of claim 1 wherein said perovskite nanocube has an outer surface that contains amorphous carbon and substantially no oxygenated groups.

10. A composition of matter comprising single crystalline SrTiO₃ nanocubes.

11. A composition of matter comprising single crystalline perovskite nanoparticles.

12. The composition of matter of claim 11 wherein said single crystalline perovskite nanoparticles have an edge length from about 1 nm to less than about 1 micron.

13. The composition of matter of claim 11 wherein said single crystalline perovskite nanoparticles have an edge length from about 75 nm to about 110 nm.

14. The composition of matter of claim 11 wherein said perovskite nanoparticle comprises a compound having the formula ABO₃ wherein B is at least one metal selected from Group IIIA, IVA, IVB, VB, VIB, VIIB, or VIIIB of the Periodic Table of Elements, and A is a combination of two additional cations having a positive formula charge of from about 1 to about 3.

15. The composition of matter of claim 14 wherein A is selected from the group consisting of K, Na, Rb, Cs, Li, Ba, Sr, Zr, Ta, La, Pb, Zn, Ca, Sc, Y, Bi, an element from the Lanthanide-series, an element from the Actinide-series, and mixtures thereof.

16. The composition of matter of claim 14 wherein A comprises a mixture of Ba, Sr, Ca.

17. The composition of matter of claim 14 wherein A is Sr/Ca and B is Ti.

18. The composition of matter of claim 14 wherein A is Ba/Ca and B is Ti.

19. The composition of matter of claim 14 wherein A is Ba/Sr/Ca and B is Ti.

20. The composition of matter of claim 11 wherein said perovskite nanoparticle has an outer surface that contains amorphous carbon and substantially no oxygenated groups.

21. The composition of matter of claim 11 wherein said perovskite nanoparticles comprise single crystalline CaₓSrₗ₋ₓTiO₃ nanoparticles where 0<x<1.

22. A composition of matter comprising single crystalline perovskite nanowires having a diameter from about 50 nm to about 80 nm and a length from about 1.5 μm or greater, said nanowire having an outer surface that contains amorphous carbon and substantially no oxygenated groups.

23. The composition of matter of claim 22 wherein said diameter is from about 1 nm to less than about 1 micron.

24. The composition of matter of claim 22 wherein said length is from about 0.5 μm to about 50 μm.

25. The composition of matter of claim 22 wherein said nanowire has an aspect ratio of about 2:1 and greater.

26. The composition of matter of claim 22 wherein said nanowire has an aspect ratio from about 2 to about 1000.

27. The composition of matter of claim 22 wherein said perovskite nanowire comprises a compound having the formula ABO₃ wherein B is at least one metal selected from Group IIIA, IVA, IVB, VB, VIB, VIIB, or VIIIB of the Periodic Table of Elements, and A is at least one additional cation having a positive formula charge of from about 1 to about 3.

28. The composition of matter of claim 27 wherein A is selected from the group consisting of K, Na, Rb, Cs, Li, Ba, Sr, Zr, Ta, La, Pb, Zn, Ca, Sc, Y, Bi, an element from the Lanthanide-series, an element from the Actinide-series, and mixtures thereof.

29. The composition of matter of claim 27 wherein A comprises Ba, Sr or a mixture thereof.

30. The composition of matter of claim 27 wherein A is Ba and B is Ti.

31. The composition of matter of claim 27 wherein A is Sr and B is Ti.

32. A method of forming a single crystalline perovskite nanostructures comprising:
admixing at least a metal oxide nanostructural template, a metal oxalate precursor compound comprising metals having a positive formula charge of 1 to 3, a surfactant and a salt that is non-reactive with the metal oxide nanostructural template to provide a reaction mixture;
sonicating the reaction mixture;
heating the reaction mixture; and
recovering single crystalline perovskite nanocubes, nanowires or a mixture thereof from the heated reaction mixture.

33. The method of claim 32 wherein said single crystalline perovskite nanostructures are nanocubes.

34. The method of claim 33 wherein said nanocubes comprise SrTiO₃.

35. The method of claim 32 wherein said single crystalline perovskite nanostructures are nanoparticles.

36. The method of claim 35 wherein said nanocubes comprise CaₓSrₗ₋ₓTiO₃ (0<x<1).

37. The method of claim 32 wherein said single crystalline perovskite nanostructures are nanowires.

38. The method of claim 37 wherein said nanowires comprise BaTiO₃.

39. The method of claim 32 wherein said metal oxide nanostructure template comprises a metal selected from Group IIIA, IVA, IVB, VB, VIB, VIIB, or VIIIB of the Periodic Table of Elements.

40. The method of claim 32 wherein said metal oxide nanostructural template comprises TiO₂.

41. The method of claim 32 wherein admixing comprises a molar ratio of the metal oxide structural template to the precursor compound from about 0.9:1 to about 1:0.9.

42. The method of claim 32 wherein said surfactant comprises a non-ionic surfactant.

43. The method of claim 32 wherein said salt comprises an alkali halide, an alkali hydroxide, an alkali nitrate, an alkali phosphate or a mixture thereof.
